(19) United States
(12) Patent Application Publication
(10) Pub. No.: US 2007/0025135 A1
(43) Pub. Date: Feb. 1, 2007

(54) Method and apparatus for regulating state of charge in battery assemble

(75) Inventors: Kouichi Yamamoto, Makinohara-shi (JP); Satoshi Ishikawa, Makinohara-shi (JP)

Correspondence Address: SUGHRUE MION, PLLC, 2100 PENNSYLVANIA AVENUE, N.W., SUITE 800, WASHINGTON, DC, 20037, US

(73) Assignee: Yazaki Corporation

(21) Appl. No.: 11/495,588

(22) Filed: Jul. 31, 2006

(30) Foreign Application Priority Data
Aug. 1, 2005 (JP) P2005-223476

(51) Int. Cl. G11C 11/00

(52) U.S. Cl. 365/132

(57) ABSTRACT

A CPU 52 detects respective voltages across unit cells B1 to Bn and extracts a minimum unit cell having a minimum voltage from the plurality of unit cells B1 to Bn based on the detected voltages. The CPU 52 sets one of cell groups each including two unit cells connected in series except the minimum unit cell as a discharge cell group, and connects the both ends of the discharge cell group to a capacitor C to transfer electric charge from the discharge cell group to the capacitor C and connects the both ends of the minimum unit cell to the capacitor C to transfer electric charge from the capacitor C to the minimum unit cell such that the respective voltages across the unit cells are equalized.

### BACKGROUND OF THE INVENTION

1. Field of the Invention

The present invention relates to a method and apparatus for regulating state of charge in a battery assembly, and more particularly, to a method and apparatus for regulating state of charge in a battery assembly which includes a plurality of secondary cells as a plurality of unit cells connected in series.

2. Description of the Related Art

In an electric car driven by an electric motor and in a hybrid electric car driven by both an engine and an electric motor, a battery assembly including secondary cells as a plurality of unit cells connected in series, such as a nickel-metal hydride battery or a lithium battery, has been employed as an electric source for the electric motor.

It has been known that the above-described battery assembly has had such a problem that due to repeated charging and discharging of electricity, variations may occur in respective voltages across the unit cells depending on the state of charge (SOC) of the unit cells, and in the case where charging and discharging of electricity are repeated while the variations remain unsolved, some of the unit cells may fall in an excessively charged state or in an excessively discharged state.

Therefore, it is proposed that unit cells are sequentially connected to a capacitor (Japanese Unexamined Patent Application Publication No. 10-225005). In this structure, electric charge of the unit cell which has a higher voltage than a voltage across the capacitor is transferred to the capacitor, and contrarily, electric charge of the capacitor is transferred to the unit cell which has a lower voltage than the voltage across the capacitor. In other words, the stored electric charge is transferred from the unit cell having the higher voltage to the unit cell having the lower voltage by way of the capacitor, and consequently, the variations in the respective voltages across the unit cells can be eliminated.

It is proposed that respective voltage across unit cells are detected, a maximum unit cell having a maximum voltage and a minimum unit cell having a minimum voltage are extracted, and a capacitor is alternately connected to the maximum unit cell and the minimum unit cell. In this structure, since the stored electric charge is transferred from the maximum unit cell to the minimum unit cell through the capacitor, the respective voltages across the unit cells can be equalized in a short time.

However, in the method which was conventionally proposed, when the variations in the respective voltage across the unit cells are large and a difference between the voltage across the maximum unit cell and the voltage across the minimum unit cell is large, the amount of the electric charge which is transferred through the capacitor is large. However, when the variations in the respective voltage across the unit cells decreases and the difference between the voltage across the maximum unit cell and the voltage across the minimum unit cell decreases by equalization, the amount of the electric charge which is transferred through the capacitor is reduced and, as a result, it takes a considerable time to completely equalize the respective voltages across the plurality of unit cells.

Accordingly, an apparatus for regulating state of charge, which connects a maximum unit cell to a capacitor through a boost converter and then connects a minimum unit cell to the capacitor, is proposed (Japanese Unexamined Patent Application Publication No. 2004-120871). According to this apparatus for regulating the state of charge, the amount of the electric charge which is transferred from the maximum unit cell to the minimum unit cell through the capacitor increases by the voltage across the maximum unit cell boosted by the boost converter, compared with the conventional case where the electric charge is transferred to the minimum unit cell according to the difference between the voltage across the maximum unit cell and the voltage across the minimum unit cell and, as a result, an equalizing time shorten. However, in this apparatus for regulating the state of charge, the boost converter is necessary and thus cost thereof increases.

### SUMMARY OF THE INVENTION

Accordingly, in view of the above-described problems, an object of the present invention is to provide a method and apparatus for regulating state of charge in a battery assembly, which can equalize respective voltages across unit cells included in the battery assembly in a short time with low cost.

In order to solve the above-described problems, according to the invention of Claim 1, there is provided a method for regulating state of charge in a battery assembly including secondary cells as a plurality of unit cells connected in series, the method including: detecting respective voltages across the unit cells; extracting a minimum unit cell having a minimum voltage from the plurality of unit cells, based on the detected voltages; setting one of cell groups each including a predetermined number of at least two unit cells connected in series except the minimum unit cell as a discharge cell group; and connecting the both ends of the discharge cell group to a capacitor to transfer electric charge from the discharge cell group to the capacitor and connecting the both ends of the minimum unit cell to the capacitor to transfer electric charge from the capacitor to the minimum unit cell such that the respective voltages across the unit cells are equalized.

According to the invention of Claim 1, one of the cell groups each including the predetermined number of at least two unit cells connected in series except the minimum unit cell is set as a discharge cell group. The both ends of the discharge cell group is connected to the capacitor to transfer the electric charge from the discharge cell group to the capacitor and the both ends of the minimum unit cell is connected to the capacitor to transfer the electric charge from the capacitor to the minimum unit cell. Accordingly, the discharge cell group is configured through the capacitor and the electric charge is transferred from the unit cell having the higher voltage than the voltage across the minimum unit cell to the minimum unit cell such that the respective voltages across the unit cells are equalized. Therefore, the voltage across the discharge cell group including at least two unit cells connected in series is surely larger than the voltage across the maximum unit cell (unit cell having a maximum voltage among the plurality of unit cells) including one unit cell. Thus, while the electric charge is transferred to the minimum unit cell by the amount of the electric charge according to a difference between the voltage across the maximum unit cell and the voltage across the minimum unit cell in the prior art, the electric charge can be transferred to the minimum unit cell by the amount of the electric charge according to a difference between the voltage across the discharge cell group and the voltage across the minimum unit cell, which is larger than the difference between the voltage across the maximum unit cell and the voltage across the minimum unit cell. Therefore, the amount of the electric charge which is transferred to the minimum unit cell through the capacitor one time can increase without using a boost converter.

According to the invention of Claim 2, there is provided an apparatus for regulating state of charge in a battery assembly including secondary cells as a plurality of unit cells connected in series, the apparatus including: voltage detecting means which detects respective voltages across the unit cells; minimum unit cell extracting means which extracts a minimum unit cell having a minimum voltage from the plurality of unit cells, based on the detected voltages; discharge cell group setting means which sets one of cell groups each including a predetermined number of at least two unit cells connected in series except the minimum unit cell as a discharge cell group; and equalizing means which connects the both ends of the discharge cell group to a capacitor to transfer electric charge from the discharge cell group to the capacitor and connects the both ends of the minimum unit cell to the capacitor to transfer electric charge from the capacitor to the minimum unit cell such that the respective voltages across the unit cells are equalized.

According to the invention of claim 2, the voltage detecting means detects the respective voltages across the unit cells. The minimum unit cell extracting means extracts the minimum unit cell having the minimum voltage from the plurality of unit cells, based on the detected voltages. The discharge cell group setting means sets one of cell groups each including a predetermined number of at least two unit cells connected in series except the minimum unit cell as the discharge cell group. The equalizing means connects the both ends of the discharge cell group to the capacitor to transfer electric charge from the discharge cell group to the capacitor and connects the both ends of the minimum unit cell to the capacitor to transfer electric charge from the capacitor to the minimum unit cell such that the respective voltages across the unit cells are equalized. Therefore, the voltage across the discharge cell group including at least two unit cells connected in series is surely larger than the voltage across the maximum unit cell (unit cell having a maximum voltage among the plurality of unit cells) including one unit cell. Thus, while the electric charge is transferred to the minimum unit cell by the amount of the electric charge according to a difference between the voltage across the maximum unit cell and the voltage across the minimum unit cell in the prior art, the electric charge can be transferred to the minimum unit cell by the amount of the electric charge according to a difference between the voltage across the discharge cell group and the voltage across the minimum unit cell, which is larger than the difference between the voltage across the maximum unit cell and the voltage across the minimum unit cell. Therefore, the amount of the electric charge which is transferred to the minimum unit cell through the capacitor one time can increase without using a boost converter.

According to the invention of Claim 3, the discharge cell group setting means has maximum cell group extracting means which, when a plurality of cell groups are extracted from the battery assembly, extracts a maximum cell group having a maximum voltage from the plurality of cell groups based on the detected voltages, and sets the extracted maximum cell group as the discharge cell group.

According to the invention of Claim 3, the maximum cell group extracting means extracts the maximum cell group having the maximum voltage from the cell groups, based on the voltages detected by the voltage detecting means. The discharge cell group setting means sets the maximum cell group as the discharge cell group. Accordingly, it is possible to further increase the difference between the voltage across the discharge cell group and the minimum unit cell and to increase the amount of the electric charge which is transferred to the minimum unit cell according to the voltage difference.

According to the invention of Claim 4, the apparatus for regulating the state of charge further includes equalized voltage estimating means which estimates an equalized voltage which is the respective voltages across the unit cells after finishing equalization by the equalizing means, based on the detected voltages, and the discharge cell group setting means sets one of the cell groups including a predetermined number of at least two unit cells except a unit cell having a voltage equal to or smaller than the estimated equalized voltage as the discharge cell group.

According to the invention of Claim 4, the equalized voltage estimating means estimates the equalized voltage which is the respective voltages across the unit cells after finishing equalization by the equalizing means, based on the voltages detected by the voltage detecting means. The discharge cell group setting means sets one of the cell groups including the predetermined number of at least two unit cells except the unit cell having the voltage equal to or smaller than the estimated equalized voltage as the discharge cell group. Accordingly, the electric charge is not transferred from the unit cell having the voltage equal to or smaller than the estimated equalized voltage to the minimum unit cell.

According to the invention of Claim 5, the equalizing means disconnects the both ends of the discharge cell group from the capacitor when the voltage across a unit cell having a minimum voltage between the unit cells included in the discharge cell group becomes the equalized voltage after the both ends of the discharge cell group are connected to the capacitor.

According to the invention of Claim 5, the equalizing means disconnects the both ends of the discharge cell group from the capacitor when the voltage across the unit cell having the minimum voltage between the unit cells included in the discharge cell group becomes the equalized voltage after the both ends of the discharge cell group are connected to the capacitor. Accordingly, it is possible to prevent the electric charge from being excessively transferred from the unit cells included in the discharge cell group to the capacitor and thus to prevent the voltage across the unit cell from being reduced less than the equalized voltage.

According to the invention of Claim 6, the apparatus further includes equalized voltage estimating means which estimates an equalized voltage which is the respective voltages across the unit cells after finishing equalization by the equalizing means, based on the detected voltages, and the equalizing means disconnects the both ends of the minimum unit cell from the capacitor when the voltage across the minimum unit cell becomes the equalized voltage after the both ends of the minimum unit cell are connected to the capacitor.

According to the invention of Claim 6, the equalized voltage estimating means estimates the equalized voltage which is the respective voltages across the unit cells after finishing equalization by the equalizing means, based on the voltages detected by the voltage detecting means. The equalizing means disconnects the both ends of the minimum unit cell from the capacitor when the voltage across the minimum unit cell becomes the equalized voltage after the both ends of the minimum unit cell are connected to the capacitor. Accordingly, it is possible to prevent the electric charge from being excessively transferred from the capacitor to the minimum unit cell and thus to prevent the voltage across the unit cell from exceeding the equalized voltage.

As described above, according to the invention of Claims 1 and 2, the voltage across the discharge cell group including at least two unit cells connected in series is surely larger than the voltage across the maximum unit cell (unit cell having a maximum voltage among the plurality of unit cells) including one unit cell. Thus, while the electric charge is transferred to the minimum unit cell by the amount of the electric charge according to a difference between the voltage across the maximum unit cell and the voltage across the minimum unit cell in the prior art, the electric charge can be transferred to the minimum unit cell by the amount of the electric charge according to a difference between the voltage across the discharge cell group and the voltage across the minimum unit cell, which is larger than the difference between the voltage across the maximum unit cell and the voltage across the minimum unit cell. Therefore, since the amount of the electric charge which is transferred to the minimum unit cell through the capacitor one time can increase without using a boost converter, the respective voltages across the unit cells included in the battery assembly can be equalized in a short time with low cost.

According to the invention of Claim 3, since it is possible to further increase the difference between the voltage across the discharge cell group and the minimum unit cell and to increase the amount of the electric charge which is transferred to the minimum unit cell according to the voltage difference, the respective voltages across the unit cells included in the battery assembly can be equalized in a shorter time.

According to the invention of Claim 4, since the electric charge is not transferred from the unit cell having the voltage equal to or smaller than the estimated equalized voltage to the minimum unit cell, the respective voltages across the unit cells included in the battery assembly can be equalized in a shorter time.

According to the invention of Claim 5, since it is possible to prevent the electric charge from being excessively transferred from the unit cells included in the discharge cell group to the capacitor and thus to prevent the voltage across the unit cell from being reduced less than the equalized voltage, the respective voltages across the unit cells included in the battery assembly can be equalized in a shorter time.

According to the invention of Claim 6, since it is possible to prevent the electric charge from being excessively transferred from the capacitor to the minimum unit cell and thus to prevent the voltage across the unit cell from exceeding the equalized voltage, the respective voltages across the unit cells included in the battery assembly can be equalized in a shorter time.

### BRIEF DESCRIPTION OF THE DRAWINGS

FIG. 1 is a circuit diagram showing an apparatus 1 for regulating state of charge in a battery assembly, which performs a method for regulating the state of charge in the battery assembly according to a first embodiment of the present invention.

FIG. 2 is a flowchart showing a state-of-charge regulating process of a CPU 52.

FIG. 3 is a flowchart showing a minimum unit cell extracting process of the CPU 52.

FIG. 4 is a flowchart showing a maximum unit cell extracting process of the CPU 52.

FIG. 5 is a flowchart showing a discharge cell group setting process of the CPU 52.

FIG. 6 is a flowchart showing an equalizing process of the CPU 52.

FIG. 7A is a partial circuit diagram showing connection between a discharge cell group and a capacitor C and FIG. 7B is a partial circuit diagram showing a minimum unit cell and the capacitor C.

### DESCRIPTION OF THE PREFERRED EMBODIMENTS

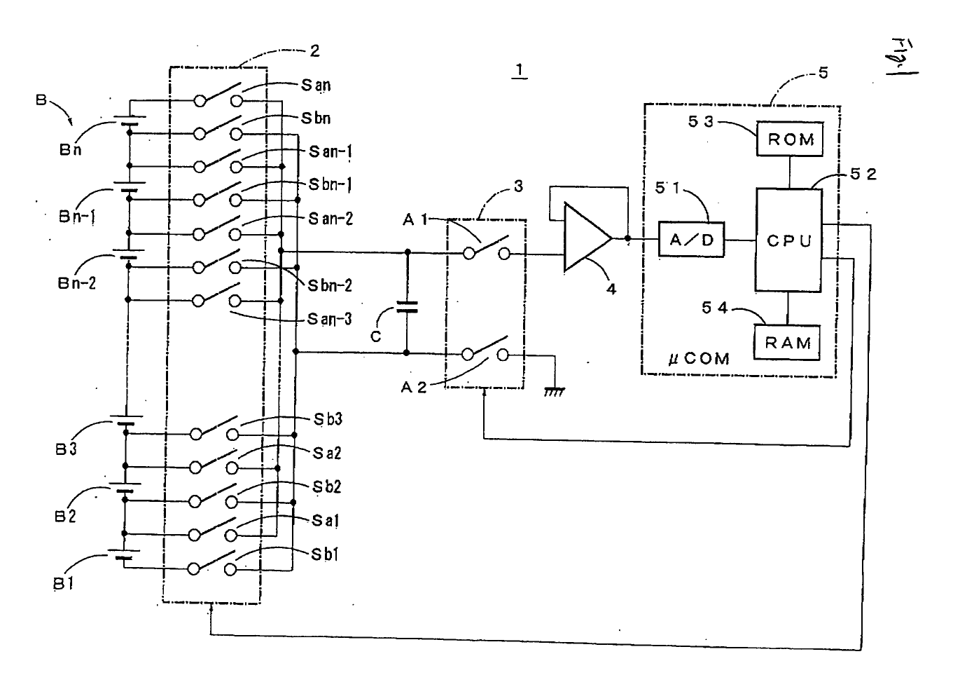

Hereinafter, an embodiment of the present invention will be described with reference to the accompanying drawings. FIG. 1 is a circuit diagram showing an apparatus 1 for regulating state of charge in a battery assembly (hereinafter, referred to as a regulating apparatus), which performs a method for regulating the state of charge in the battery assembly according to a first embodiment of the present invention. In Figure, a reference numeral 1 denotes the apparatus for regulating the state of charge in the main battery B (battery assembly) which includes second cells as a plurality of unit cells B1, B2, B3 to Bn−1 and Bn connected in series.

The main battery B is, for example, used as an electric source in a hybrid electric car employing both an engine and an electric motor (both are not shown) as driving sources. The electric motor or the like is connected the both ends of the main battery B as a load according to necessity, and an alternator or the like (not shown) is connected thereto as a charging device according to necessity.

The regulating apparatus 1 according to the present embodiment includes a cell selecting switch group 2, a voltage detecting switch group 3, a buffer circuit 4, a microcomputer (hereinafter, referred to as μCOM) 5 and a capacitor C.

The cell selecting switch group 2 is provided between the main battery B and the capacitor C, selectively connects any one of the unit cells B1 to Bn included in the main battery B to the capacitor C, and includes n pairs of switches Sa1 and Sb1, Sa2 and Sb2, . . . , San−1 and Sbn−1 and San and Sbn. More specifically, the switches Sa1, Sa2, . . . , San−1 and San are connected between the positive terminals of the unit cells B1 to Bn and one end (a terminal located at the upper side of Figure) of the capacitor C and the switches Sb1, Sb2, . . . , Sbn−1 and Sbn are connected between the negative terminals of the unit cells B1 to Bn and the other end (a terminal located at the lower side of Figure) of the capacitor C.

The voltage detecting switch group 3 is provided between the capacitor C and the μCOM 5 and includes a pair of switches A1 and A2. The switch A1 is connected between one end of the capacitor C and the buffer circuit 4 and the switch A2 is connected between the other end of the capacitor C and ground. As the buffer circuit 4, for example, an operational amplifier is used. The voltage across the capacitor C is output to an analog/digital (A/D) converter 51 of the μCOM 5 through the buffer circuit 4. The A/D converter 51 may be embedded in the μCOM 5, as shown in FIG. 1, or may be provided independent of the μCOM 5.

The μCOM 5 has the A/D converter 51, a central processing unit (CPU) 52 for performing various processes or controls according to programs, a read-only memory (ROM) 53 which stores the programs for the processes of the CPU 52, a random access memory (RAM) 54 which stores various data and has work areas for reading and writing to be utilized in the various processes of the CPU 52.

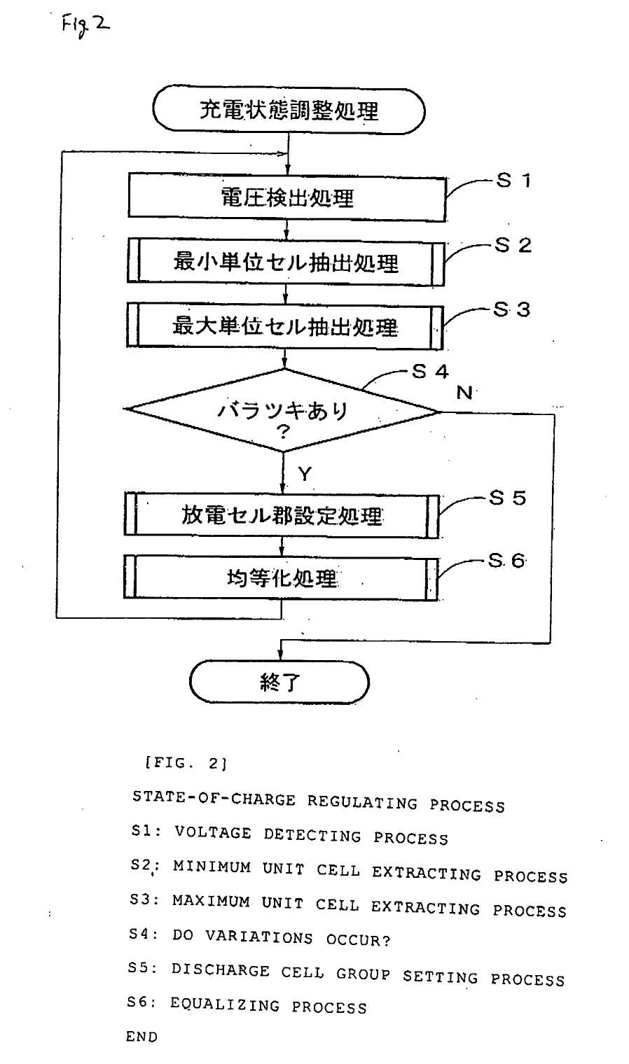

Hereinafter, the operation of the regulating apparatus 1 having the above-described structure will be described with reference to a flowchart showing a state-of-charge regulating process of the CPU 52 shown in FIG. 2. The CPU 52 included in the μCOM 5 initiates the state-of-charge regulating process by turning on an ignition switch. In the state-of-charge regulating process, first, the CPU 52 performs a voltage detecting process for detecting the respective voltages across the unit cells B1 to Bn (step S1).

In the voltage detecting process, first, in order to detect the voltage across the unit cell B1, the CPU 52 turns off the switches A1 and A2 to disconnect the capacitor C from the μCOM 5 and turns on the switches Sa1 and Sb1 to connect the both ends of the unit cell B1 to the capacitor C. As a result, the voltage across the capacitor C becomes equal to the voltage across the unit cell B1.

Next, the CPU 52 turns off the switches Sa1 and Sb1 to disconnect the capacitor C from the main battery B and turns on the switches A1 and A2. As a result, the voltage across the capacitor C equal to the voltage across the unit cell B1 is output to the A/D converter 51 through the buffer circuit 4. The CPU 52 reads the digital value of the voltage across the capacitor C output from the A/D converter 51 and stores the digital value in the RAM 54 as the voltage across the unit cell B1. Similarly, the CPU 52 sequentially detects the voltages across the unit cells B2, . . . Bn−1 and Bn using the capacitor C. As can be seen from above, the cell selecting switch group 2, the voltage detecting switch group 3 and the CPU 52 configure voltage detecting means of claims.

Next, the CPU 52 acts as minimum unit cell extracting means and performs a minimum unit cell extracting process for extracting a minimum unit cell Bmin having a minimum voltage from the unit cells 51 to Bn, based on the voltages across the unit cells detected by the voltage detecting process (step S2).

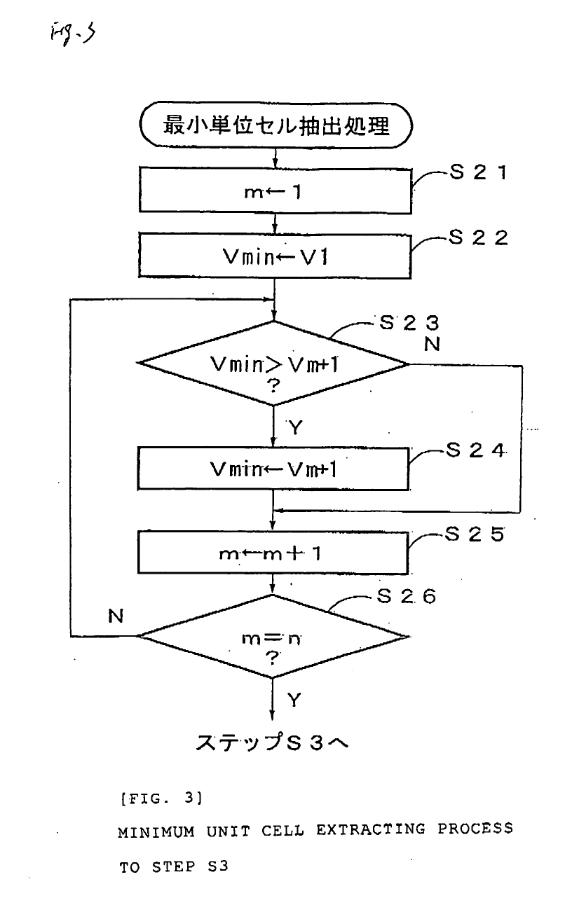

The minimum unit cell extracting process will be described with reference to FIG. 3. First, the CPU 52 sets a count value m to 1 (step 521) and sets the voltage V1 across the unit cell B1 as a voltage Vmin across the minimum unit cell Bmin (step S22). Next, the voltage Vmin across the minimum unit cell Bmin is compared with a voltage Vm+1 across a unit cell Bm+1 (step S23). If the voltage Vmin across the minimum unit cell Smin is larger than the voltage Vm+1 across the unit cell Bm+1 (Y in the step S23), the CPU 52 sets the voltage Vm+1 across the unit cell Bm+1 as the voltage Vmin across the minimum unit cell Bmin (step 524) and then increases the count value m by one (step S25).

Meanwhile, if the voltage Vmin across the minimum unit cell Bmin is smaller than the voltage Vm+1 across the unit cell Bm+1 (N in the step 523), the CPU 52 progresses the process to a step $25. Next, the CPU 52 determines whether the count value m becomes n (step S26). If the count value m does not become n (N in the step S26), the CPU 52 returns the process to the step S23. Meanwhile, if the count value m becomes n (Y in the step S26), the CPU 52 finishes the minimum unit cell extracting process and progresses the process to a step S3.

In the step S3, the CPU 52 performs a maximum unit cell extracting process for extracting a maximum unit cell Bmax having a maximum voltage from the unit cells B1 to Bn, based on the voltages across the unit cells detected by the voltage detecting process.

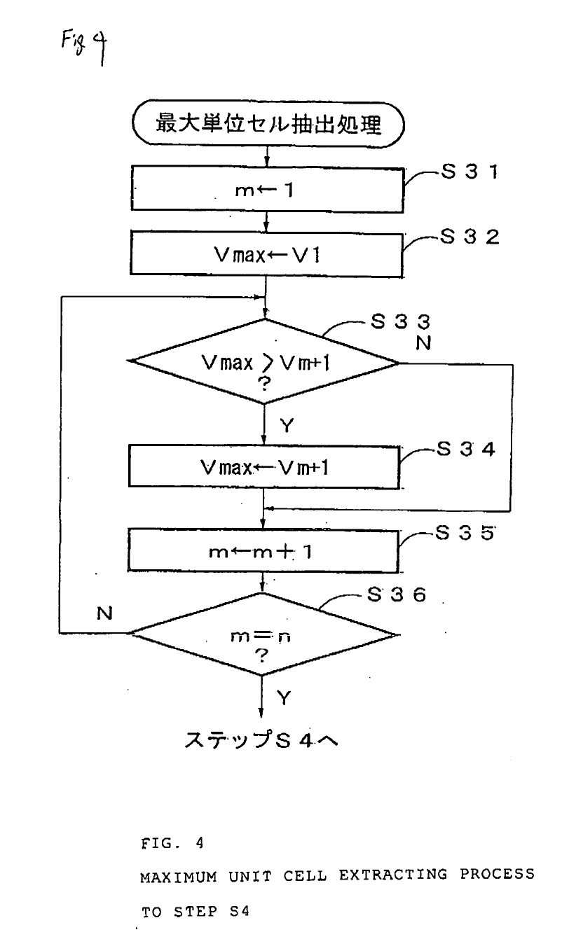

Hereinafter, the maximum unit cell extracting process will be described with reference to FIG. 4. First, the CPU 52 sets a count value m to 1 (step S31) and sets the voltage V1 across the unit cell B1 as a voltage Vmax across the maximum unit cell Bmax (step 532). Next, the voltage Vmax across the maximum unit cell Bmax is compared with the voltage Vm+1 across the unit cell Bm+1 (step S33). If the voltage Vmax across the maximum unit cell Bmax is smaller than the voltage Vm+1 across the unit cell Bm+1 (Y in the step S33), the CPU 52 sets the voltage Vm+1 across the unit cell Bm+1 as the voltage Vmax across the maximum unit cell Bmax (step 534) and then increases the count value m by one (step S35).

Meanwhile, if the voltage Vmax across the maximum unit cell Bmax is larger than the voltage Vm+1 across the unit cell Dm+1 (N in the step S33), the CPU 52 progresses the process to a step 535. Next, the CPU 52 determines whether the count value m becomes n (step S36). If the count value m does not become n (N in the step S36), the CPU 52 returns the process to the step S33. Meanwhile, if the count value m becomes n (Y in the step S36), the CPU 52 finishes the maximum unit cell extracting process and progresses the process to a step S4.

Next, as shown in FIG. 2, if a difference (Vmax−Vmin) between the extracted voltage across the minimum unit cell Bmin and the extracted voltage Vmax across the maximum unit cell Bmax is smaller than a threshold value (N in the step S4), the CPU 52 determines that variations do not occur in the respective voltages across the unit cells B1 to Bn, and finishes the state-of-charge regulating process. Meanwhile, if the difference (Vmax−Vmin) is larger than the threshold value (Y in the step S4), the CPU 52 determines that the variations occur in the respective voltages across the unit cells B1 to Bn and progresses the process to a step S5.

In the step 55, the CPU 52 acts as discharge cell group setting means and performs a discharge cell group setting process for setting one of cell groups including two (predetermined number) unit cells connected in series except the minimum unit cell Bmin as a discharge cell group (step S5). In the present embodiment, an example for excluding a unit cell having a voltage equal to or smaller than the below-described equalized voltage in addition to the minimum unit cell Bmin will be described.

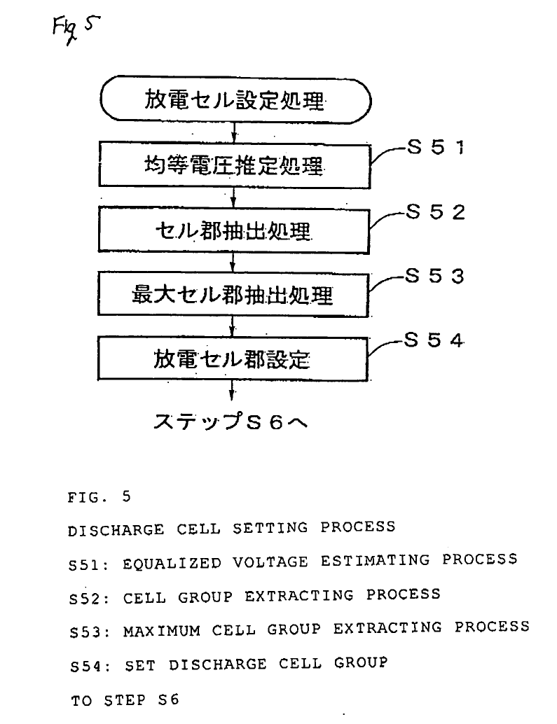

The discharge cell group setting process will be described with reference to FIG. 5. First, the CPU 52 acts as equalized voltage estimating means and performs an equalized voltage estimating process for estimating an equalized voltage which is the respective voltages across the unit cells B1 to Bn after equalization, based on the respective voltages V1 to Vn across the unit cells B1 to Bn (step S51). More specifically, an average voltage {(V1−Vn)/n} of the voltages V1 to Vn may be set as the equalized voltage. Alternatively, an average amount of the stored electric charge in the unit cells B1 to Bn is obtained from the voltages V1 to Vn and the voltage across each of the unit cells B1 to Bn corresponding to the obtained average amount of the stored electric charge may be set as the equalized voltage.

Next, the CPU 52 performs a cell group extracting process for extracting cell groups each including two unit cells connected in series from the main battery B except the minimum unit cell Bmin and the unit cell having the voltage equal to or smaller than the equalized voltage (step S52). As the cell groups each including the two unit cells connected in series, n−1 cell groups including a cell group Bg1 including the unit cells B1 and B2, a cell group Bg2 including the unit cells B2 and B3, . . . , a cell group Bgn−2 including the unit cells Bn−2 and Bn−1 and a cell group Bgn−1 including the unit cells Bn−1 and Bn are previously extracted and stored in the ROM 53.

In the cell group extracting process, the CPU 52 extracts the cell groups except the cell group including the minimum unit cell Bmin and the unit cell having the voltage equal to or smaller than the equalized voltage from the cell groups Bg1 to Bgn−1 stored in ROM 53 and stores the cell groups in the RAM 54.

Next, the CPU 52 acts as maximum cell group extracting means and performs a maximum cell group extracting process for extracting a maximum cell group having a maximum voltage from a plurality of cell groups based on the voltages detected by the voltage detecting process when the plurality of cell groups is extracted from the main battery B by the cell group extracting process (step S53). Thereafter, the CPU 52 sets the extracted maximum cell group as the discharge cell group (step S54) and progresses the process a step S6. When the state of charge is regulated in the main battery B in which the number of the unit cells B1 to Bn is small and only one cell group is extracted by the cell group extracting process, the one cell group is set as the discharge cell group and the maximum cell group extracting process is not performed.

In the step S6 shown in FIG. 2, the CPU 52 connects the both ends of the discharge cell group to the capacitor C to transfer the electric charge from the discharge cell group to the capacitor C and then connects the both ends of the minimum unit cell to the capacitor C to transfer the electric charge from the capacitor C to the minimum unit cell, thereby performing an equalizing process for equalizing the respective voltages across the unit cells.

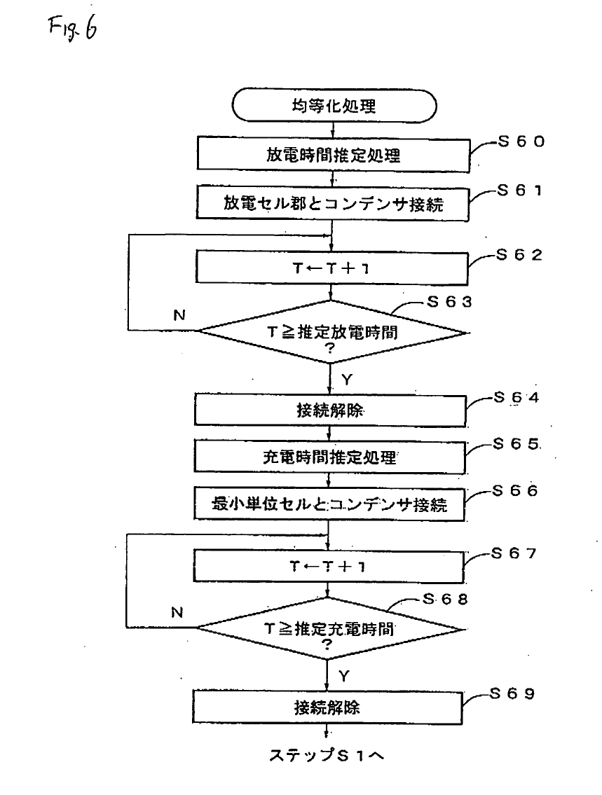

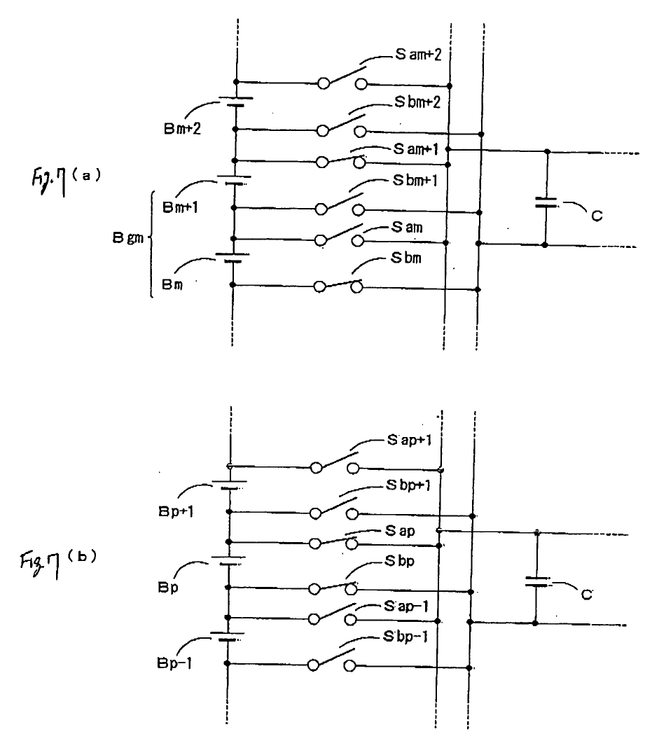

More specifically, as shown in a flowchart of FIG. 6, first, the CPU 52 performs a discharge duration estimating process for estimating a discharge duration from a time when the both ends of the discharge cell group is connected to the capacitor C to a time when the voltage across a unit cell having a minimum voltage between the unit cells included in the discharge cell group becomes the equalized voltage (step S60). Next, as shown in FIG. 7A, when a cell group Bgm including unit cells Bm and Bm+1 is set as the discharge cell group, the unit cells CPU 52 turns on switches Sbm and Sam+1 and connects the both ends of the cell group Bgm, which is set as the discharge cell group, to the capacitor C (step 561), and initiates the count of elapsed time T (step S62). The discharge cell group is discharged by the above-described connection and the electric charge is transferred from the discharge cell group to the capacitor C.

When the elapsed time T becomes the discharge duration estimated in the discharge duration estimating process (Y in the step S63), the CPU 52 determines that the voltage across the unit cell having the minimum voltage between the unit cells included in the discharge cell group becomes the equalized voltage, turns off the switches Sbm and Sam+1, and disconnects the discharge cell group from the capacitor C (step S64).

Next, the CPU 52 turns on the switches A1 and A2 to measure the voltage across the capacitor C and performs a charge duration estimating process for estimating a charge duration from a time when the both ends of the minimum unit cell Bmin to the capacitor C to a time when the voltage across the minimum unit cell Bmin becomes the equalized voltage, based on the voltage Vmin across the minimum unit cell Bmin and the voltage across the capacitor C (step S65) Thereafter, as shown in FIG. 7B, when the minimum unit cell Bmin is a unit cell Bp, the CPU 52 turns on the switches Sap and Sbp, connects the both ends of the minimum unit cell Bmin to the capacitor C (step S66), and initiates the count of the elapsed time T (step S67). The capacitor C is discharged by the above-described connection and the electric charge is transferred from the capacitor to the minimum unit cell Bmin.

When the elapsed time T becomes the charge duration estimated in the charge duration estimating process (Y in the step S68), the CPU 52 determines that the voltage across the minimum unit cell Bmin becomes the equalized voltage, turns off the switches Sap and Sbp, disconnects the minimum unit cell Bmin from the capacitor C (step S69), and returns the process to the step S1. As can be seen from above, the cell selecting switch group 2 and the CPU 5 configure equalizing means of claims.

According to the above-described apparatus for regulating the state of charge, the CPU 52 detects the respective voltages across the unit cells B1 to Bn by the voltage detecting process of the step S1 and extracts the minimum unit cell Bmin having the minimum voltage from the plurality of unit cells S1 to Bn based on the detected voltages, by the minimum unit cell extracting process of the step 52. The CPU 52 sets one of the cell groups including two unit cells connected in series except the minimum unit cell Bmin as the discharge cell group by the discharge cell group setting process of the step S5, and connects the both ends of the discharge cell group to the capacitor C to transfer the electric charge from the discharge cell group to the capacitor C and connects the both ends of the minimum unit cell Bmin to the capacitor C to transfer the electric charge from the capacitor C to the minimum unit cell Bmin to equalize the respective voltages across the unit cells B1 to Bn, by the equalizing process of the step S6.

Accordingly, the voltage across the discharge cell group including the two unit cells connected in series is surely larger than the voltage across the maximum unit cell Bmax including one unit cell. Thus, while the electric charge is transferred to the minimum unit cell Bmin by the amount of the electric charge according to the difference between the voltage across the maximum unit cell Bmax and the voltage across the minimum unit cell Bmin in the prior art, the electric charge can be transferred to the minimum unit cell Bmin by the amount of the electric charge according to the difference between the voltage across the discharge cell group and the voltage across the minimum unit cell group Bmin, which is larger than the difference between the voltage across the maximum unit cell Bmax and the voltage across the minimum unit cell Bmin. Therefore, the amount of the electric charge which is transferred to the minimum unit cell Bmin through the capacitor C once can increase without using a boost converter and, as a result, the respective voltages across the unit cells B1 to Bn included in the main battery B can be equalized in a short time with low cost.

According to the apparatus for regulating the state of charge, the CPU 52 extracts the maximum cell group having the maximum voltage from the plurality of cell groups extracted in the step S52 by the maximum cell group extracting process of the step S53 and sets the maximum cell group extracted in the step 354 as the discharge cell group. Accordingly, the difference between the voltage across the discharge cell group and the voltage across the minimum unit cell Bmin can increase and the amount of the electric charge which is transferred to the minimum unit cell Bmin through the capacitor C once increases depending on the difference in the voltage. As a result, the respective voltages across the unit cells B1 to Bn included in the main battery B can be equalized in a shorter time.

According to the apparatus for regulating the state of charge, the CPU 52 sets one of the cell groups including two unit cells except the unit cell having the voltage equal to or smaller than the estimated equalized voltage as well as the minimum unit cell Bmin as the discharge cell group, by the discharge cell setting process of the step S5. Accordingly, the electric charge is not transferred from the unit cell having the voltage equal to or smaller than the estimated equalized voltage to the minimum unit cell Bmin. As a result, the respective voltages across the unit cells B1 to Bn included in the main battery B can be equalized in a shorter time.

When the connection between the both ends of the discharge cell group and the capacitor C is maintained until the electric charge is not transferred between the discharge cell group and the capacitor C, the unit cells included in the discharge cell group may be excessively discharged and become smaller than the equalized voltage. Accordingly, the electric charge must be transferred from the other unit cell to the unit cell across which the voltage becomes smaller than the equalized voltage and, as a result, it takes a considerable time to perform the equalization. According to the apparatus for regulating the state of charge, the CPU 52 determines that the voltage across a unit cell having a minimum voltage between the unit cells included in the discharge cell group becomes the equalized voltage when the discharge duration estimated by the discharge duration estimating process of the step S60 elapses after the both ends of the discharge cell group are connected to the capacitor C, and disconnects the both ends of the discharge cell group from the capacitor C, in the equalizing process of the step S6. As a result, since it is possible to prevent the voltages across the unit cells included in the discharge cell group from being reduced to less than the equalized voltage, it is possible to equalize the respective voltages across the unit cells B1 to Bn included in the main battery B in a shorter time.

When the connection between the both ends of the minimum unit cell Bmin and the capacitor C is maintained until the electric charge is not transferred between the minimum unit cell Bmin and the capacitor C, the minimum unit cell Bmin may be excessively charged and become larger than the equalized voltage. Accordingly, the electric charge must be transferred from the unit cell across which the voltage becomes larger than the equalized voltage to the other unit cell and thus it takes a considerable time to perform the equalization. According to the apparatus for regulating the state of charge, the CPU 52 determines that the voltage across the minimum unit cell Bmin becomes the equalized voltage when the charge duration estimated by the charge duration estimating process of the step S65 elapses after the both ends of the minimum unit cell Bmin are connected to the capacitor C, and disconnects the both ends of the minimum unit cell Bmin from the capacitor C, in the equalizing process of the step S6. As a result, since it is possible to prevent the voltage across the minimum unit cell Bmin from exceeding the equalized voltage, it is possible to equalize the respective voltages across the unit cells B1 to Bn included in the main battery B in a shorter time.

In the above-described embodiment, as the cell selecting switch group 2, the pairs of switches Sa1 and Sb1 to San and Sbn are provided at the both ends of the unit cells B1 to Bn, respectively. That is, the cell selecting switch group 2 includes 2n switches and two switches are connected between the unit cells. However, as the cell selecting switch group 2, one of the plurality of unit cells B1 to Bn may be connected to the capacitor C and, for example, the cell selecting switch group 2 may include n+1 switches and a polarity reversing switch and one switch may be connected between the unit cells.

In the above-described embodiment, the cell groups including two unit cells connected in series except the unit cell having the voltage equal to or smaller than the equalized voltage and the minimum unit cell Bmin are extracted in the cell group extracting process of the step 552. However, the present invention is not limited thereto. For example, the unit cell having the voltage equal to or smaller than the equalized voltage may not be excluded and the cell groups including the two unit cells connected in series except the minimum unit cell Bmin may be extracted. Although the predetermined number of at least two is two in the present embodiment, the present invention is not limited thereto and the predetermined number may be three or four.

In the above-described embodiment, the cell groups except the minimum unit cell Bmin and the unit cell having the voltage equal to or smaller than the equalized voltage are previously extracted from the cell groups Bg1 to Bgn−1 each including two unit cells connected in series in the cell group extracting process of the step S52 and the maximum cell group having the maximum voltage is extracted from the extracted cell groups. However, the present invention is not specially limited as long as the maximum cell group having the maximum voltage is extracted from the cell groups including the two unit cells except the minimum unit cell Bmin and the unit cell having the voltage equal to or smaller than the equalized voltage. For example, after the maximum cell group having the maximum voltage is extracted from the cell groups Bg1 to Bgn−1 including the two unit cells connected in series, the extracted maximum cell group may be set as the discharge cell group when the unit cells included in the maximum cell group do not include the minimum unit cell Bmin or the unit cell having the voltage equal to or smaller than the equalized voltage, and a cell group having a second largest voltage may be extracted as the maximum cell group when the unit cells included in the extracted maximum cell group include the minimum unit cell Bmin or the unit cell having the voltage equal to or smaller than the equalized voltage.

In the above-described embodiment, when the discharge duration estimated by the discharge duration estimating process elapses after the discharge cell group is connected to the capacitor C, it is determined that the voltage across the unit cell having the minimum voltage between the unit cells included in the discharge cell group becomes the equalized voltage and the both ends of the discharge cell group are disconnected from the capacitor C. When the charge duration estimated by the charge duration estimating process elapses after the minimum unit cell Bmin is connected to the capacitor C, it is determined that the voltage across the minimum unit cell becomes the equalized voltage and the both ends of the minimum unit cell Bmin are disconnected from the capacitor C. However, if the voltages across the unit cells B1 to Bn can be detected during discharging or charging, it can be determined that the voltage across the unit cell having the minimum voltage between the unit cells included in the discharge cell group or the voltage across the minimum unit cell Bmin becomes the equalized voltage, based on the detected result. When the electric charge is not transferred between the discharge cell group and the capacitor C and between the minimum unit cell Bmin and the capacitor C, the disconnection may be performed. Alternatively, the disconnection may be performed in a predetermined time after the connection.

The above-described embodiments are only representative aspects of the present invention and the present invention is not limited to the embodiments. That is, the present invention may be variously changed without departing from the spirit of the present invention.

What is claimed is:

1. A method for regulating state of charge in a battery assembly including secondary cells as a plurality of unit cells connected in series, the method comprising the steps of:
detecting respective voltages across the unit cells;
extracting a minimum unit cell having a minimum voltage from the plurality of unit cells, based on the detected voltages;
setting one of cell groups each including a predetermined number of at least two unit cells connected in series except the minimum unit cell as a discharge cell group; and
connecting the both ends of the discharge cell group to a capacitor to transfer electric charge from the discharge cell group to the capacitor and connecting the both ends of the minimum unit cell to the capacitor to transfer electric charge from the capacitor to the minimum unit cell such that the respective voltages across the unit cells are equalized.

2. An apparatus for regulating state of charge in a battery assembly including secondary cells as a plurality of unit cells connected in series, the apparatus comprising:
a voltage detector, which detects respective voltages across the unit cells;
a minimum unit cell extractor, which extracts a minimum unit cell having a minimum voltage from the plurality of unit cells, based on the detected voltages;
a discharge cell group setter, which sets one of cell groups each including a predetermined number of at least two unit cells connected in series except the minimum unit cell as a discharge cell group; and
an equalizer, which connects the both ends of the discharge cell group to a capacitor to transfer electric charge from the discharge cell group to the capacitor and connects the both ends of the minimum unit cell to the capacitor to transfer electric charge from the capacitor to the minimum unit cell such that the respective voltages across the unit cells are equalized.

3. The apparatus for regulating state of charge according to claim 2, wherein the discharge cell group setter has a maximum cell group extractor, which, when a plurality of cell groups are extracted from the battery assembly, extracts a maximum cell group having a maximum voltage from the plurality of cell groups based on the detected voltages, and sets the extracted maximum cell group as the discharge cell group.

4. The apparatus for regulating state of charge according to claim 2, further comprising:
an equalized voltage estimator, which estimates
an equalized voltage which is the respective voltages across the unit cells after finishing equalization by the equalizer, based on the detected voltages, and
wherein the discharge cell group setter sets one of the cell groups including a predetermined number of at least two unit cells except a unit cell having a voltage equal to or smaller than the estimated equalized voltage as the discharge cell group.

5. The apparatus for regulating state of charge according to claim 4, wherein the equalizer disconnects the both ends of the discharge cell group from the capacitor when the voltage across a unit cell having a minimum voltage between the unit cells included in the discharge cell group becomes the equalized voltage after the both ends of the discharge cell group are connected to the capacitor.

6. The apparatus for regulating state of charge according to claim 2, further comprising equalized voltage estimator which estimates an equalized voltage which is the respective voltages across the unit cells after finishing equalization by the equalizer, based on the detected voltages, and
wherein the equalizer disconnects the both ends of the minimum unit cell from the capacitor when the voltage across the minimum unit cell becomes the equalized voltage after the both ends of the minimum unit cell are connected to the capacitor.
